(19) United States
(12) Patent Application Publication
(10) Pub. No.: US 2019/0169018 A1
(43) Pub. Date: Jun. 6, 2019

(54) STRESS ISOLATION FRAME FOR A SENSOR

(71) Applicant: InvenSense, Inc., San Jose, CA (US)

(72) Inventors: Doruk SENKAL, San Jose, CA (US); Yang LIN, Fremont, CA (US); Houri JOHARI-GALLE, San Jose, CA (US); Joseph SEEGER, Menlo Park, CA (US)

(73) Assignee: InvenSense, Inc., San Jose, CA (US)

(21) Appl. No.: 15/985,283

(22) Filed: May 21, 2018

Related U.S. Application Data
(60) Provisional application No. 62/595,015, filed on Dec. 5, 2017.

(51) Int. Cl. B81B 7/00

(52) U.S. Cl. CPC B81B 7/0045; B81B 2201/0235; B81B 2201/0278; B81B 2201/0257; B81B 2201/0264; B81B 2201/0242

(57) ABSTRACT

A device for reducing package stress sensitivity of a sensor includes one or more anchor points for attaching to a substrate; a rigid frame structure configured to at least partially support the sensor; and a compliant element between each anchor point and the rigid frame structure. Also disclosed is a device for supporting a micro-electro-mechanical (MEMS) sensor comprising four anchor points for attaching to a substrate; a rigid frame structure configured to support the MEMS sensor; and a crab-leg suspension element between each anchor point and the rigid frame structure, wherein the crab-leg suspension element is compliant. A method for reducing package stress sensitivity of a sensor is provided as well.

### RELATED APPLICATIONS

This application claims priority to and the benefit of co-pending U.S. Patent Provisional Patent Application 62/595,015, filed on Dec. 5, 2017, entitled “STRESS ISOLATION FRAME FOR MEMS DEVICE,” by Senkal et al., having Attorney Docket No. IVS-769.PR, and assigned to the assignee of the present application, which is incorporated herein by reference in its entirety.

### BACKGROUND

A sensor is a device, module, or subsystem whose purpose is to detect events or changes in its environment and send the information to other electronics, frequently a computer processor. There are many types of sensors, including magnetometers, clocks, accelerometers, gyroscopes, microphones, and pressure sensors. Of interest herein are micro-electro-mechanical systems (MEMS), which are based on the technology of microscopic devices, particularly those with moving parts. Examples of MEMS sensors include clocks, gyroscopes, accelerometers, Lorentz force magnetometers, and membrane sensors such as microphones and pressure sensors.

Micro-electro-mechanical systems (MEMS) technology has been under steady development for some time, and as a result, various MEMS sensors (e.g., accelerometers for measuring linear acceleration and gyroscopes for measuring angular velocity) have been implemented within several applications. For example, individual accelerometer and gyroscope sensors are currently being used in vehicle air bag controls, gaming consoles, digital cameras, video cameras, and mobile phones.

### BRIEF DESCRIPTION OF THE DRAWINGS

The accompanying drawings, which are incorporated in and form a part of the Description of Embodiments, illustrate various embodiments of the subject matter and, together with the Description of Embodiments, serve to explain principles of the subject matter discussed below. Unless specifically noted, the drawings referred to in this Brief Description of Drawings should be understood as not being drawn to scale. Herein, like items are labeled with like item numbers.

FIG. 1 is a block diagram of an example mobile electronic device that includes a MEMS sensor.

FIGS. 2A-C are diagrams illustrating schematic top plan views of a device for reducing package stress sensitivity of a sensor, according to some embodiments.

FIGS. 3A through 3D are diagrams illustrating examples of different shapes of a rigid frame structure, according to some embodiments. FIG. 3B is an enlargement of a portion of FIG. 3A.

FIGS. 4A-C are each a diagram illustrating examples of different crab-leg compliant structures employed in the devices shown in FIGS. 2A-C, according to some embodiments.

FIGS. 5A-F are each a diagram illustrating examples of folded spring compliant structures employed in the devices shown in FIGS. 2A-C, according to some embodiments.

FIG. 6 is a flow chart illustrating one embodiment of a method for reducing package stress sensitivity of the sensor.

### DESCRIPTION OF EMBODIMENTS

The following Description of Embodiments is merely provided by way of example and not of limitation. Furthermore, there is no intention to be bound by any expressed or implied theory presented in the preceding background or in the following Description of Embodiments.

Reference will now be made in detail to various embodiments of the subject matter, examples of which are illustrated in the accompanying drawings. While various embodiments are discussed herein, it will be understood that they are not intended to limit to these embodiments. On the contrary, the presented embodiments are intended to cover alternatives, modifications and equivalents, which may be included within the spirit and scope the various embodiments as defined by the appended claims. Furthermore, in this Description of Embodiments, numerous specific details are set forth in order to provide a thorough understanding of embodiments of the present subject matter. However, embodiments may be practiced without these specific details. In other instances, well known methods, procedures, components, and circuits have not been described in detail as not to unnecessarily obscure aspects of the described embodiments.

### Notation and Nomenclature

Some portions of the detailed descriptions which follow are presented in terms of procedures, logic blocks, processing and other symbolic representations of operations on data within an electrical device. These descriptions and representations are the means used by those skilled in the data processing arts to most effectively convey the substance of their work to others skilled in the art. In the present application, a procedure, logic block, process, or the like, is conceived to be one or more self-consistent procedures or instructions leading to a desired result. The procedures are those requiring physical manipulations of physical quantities. Usually, although not necessarily, these quantities take the form of sensed linear acceleration, angular velocity magnetic fields, and pressure, for example.

It should be borne in mind, however, that all of these and similar terms are to be associated with the appropriate physical quantities and are merely convenient labels applied to these quantities. Unless specifically stated otherwise as apparent from the following discussions, it is appreciated that throughout the description of embodiments, discussions utilizing terms such as “providing,” “capturing,” “combining,” “receiving,” “sensing,” or the like, refer to the actions and processes of an electronic device such as a sensor.

In the figures, a single block may be described as performing a function or functions; however, in actual practice, the function or functions performed by that block may be performed in a single component or across multiple components, and/or may be performed using hardware. To clearly illustrate this interchangeability of hardware and software, various illustrative components, blocks, modules, logic, circuits, and steps have been described generally in terms of their functionality. Whether such functionality is implemented as hardware depends upon the particular application and design constraints imposed on the overall system. Skilled artisans may implement the described functionality in varying ways for each particular application, but such implementation decisions should not be interpreted as causing a departure from the scope of the present disclosure. Also, the example systems described herein may include components other than those shown, including well-known components.

As used herein, a gyroscope is a sensor used for measuring or maintaining orientation and angular velocity. A MEMS-based gyroscope is a miniaturized gyroscope found in electronic devices. It takes the idea of the Foucault pendulum and uses a vibrating element.

The terms “rigid” and “compliant” are used in the context of their customary definitions. That is to say, “rigid” as applied to a structure means unable to bend or be forced out of shape; not flexible, while “compliant” as applied to a structure means the ability of that structure to yield elastically when a force is applied.

It is to be noted that, as used in this specification and the appended claims, the singular forms “a,” “an” and “the” include plural referents unless the context clearly dictates otherwise. Also, any reference herein to “top”, “bottom”, “upper”, “lower”, “up”, “down”, “front”, “back”, “first”, “second”, “left” or “right” is not intended to be a limitation herein. Herein, the term “about” when applied to a value generally means within the tolerance range of the equipment used to produce the value, or may mean plus or minus 10%, or plus or minus 5%, or plus or minus 1%, unless otherwise expressly specified. Further, the terms “substantially” and “about”, as used herein, mean a majority, or almost all, or all, or an amount within a range of about 51% to about 100%. It is appreciated that, in the following description, numerous specific details are set forth to provide a thorough understanding of the examples. However, it is appreciated that the examples may be practiced without limitation to these specific details. In other instances, well-known methods and structures may not be described in detail to avoid unnecessarily obscuring the description of the examples. Also, the examples may be used in combination with each other.

### Overview of Discussion

Discussion begins with a description of an example mobile electronic device with which or upon which various embodiments described herein may be implemented. In particular, the mobile electronic device includes a MEMS sensor, such as a gyroscope. A description of an improved stress isolation frame for MEMS sensors and other sensors is then provided.

### Example Mobile Electronic Device

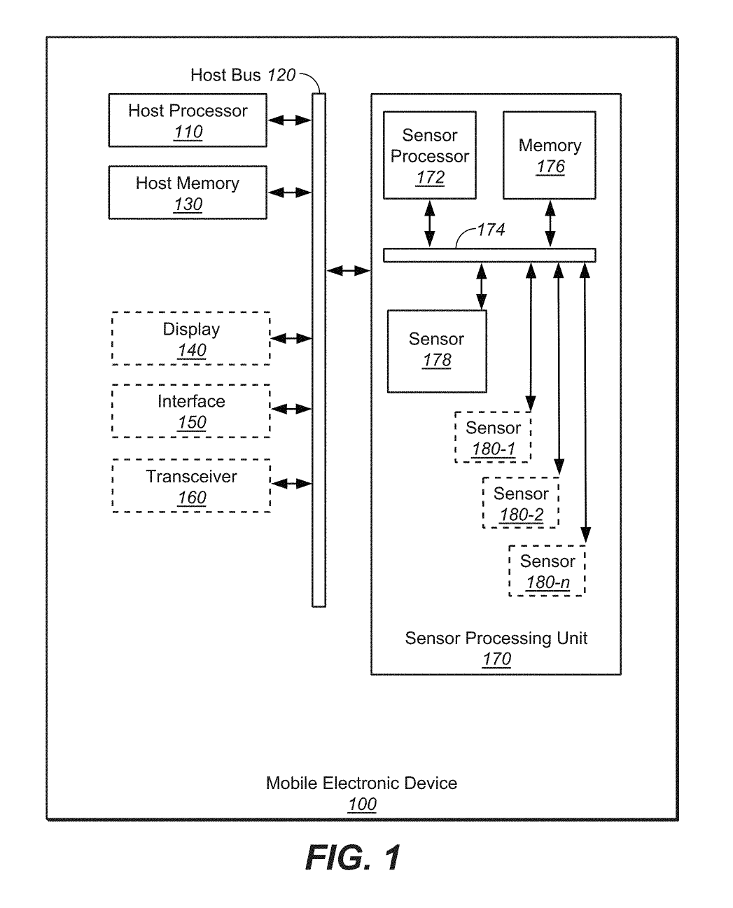

Turning now to the figures, FIG. 1 is a block diagram of an example mobile electronic device 100 that includes a MEMS sensor, such as a gyroscope. As will be appreciated, mobile electronic device 100 may be implemented as a device or apparatus, such as a handheld mobile electronic device. For example, such a mobile electronic device may be, without limitation, a mobile telephone phone (e.g., smartphone, cellular phone, a cordless phone running on a local network, or any other cordless telephone handset), a wired telephone (e.g., a phone attached by a wire), a personal digital assistant (PDA), a video game player, video game controller, a navigation device, an activity or fitness tracker device (e.g., bracelet, clip, band, or pendant), a smart watch or other wearable device, a mobile Internet device (MID), a personal navigation device (PND), a digital still camera, a digital video camera, a portable music player, a portable video player, a portable multi-media player, a remote control, or a combination of one or more of these devices.

As depicted in FIG. 1, mobile electronic device 100 may include a host processor 110, a host bus 120, a host memory 130, a display 140, and a sensor processing unit (SPU) 170. Some embodiments of mobile electronic device 100 may further include one or more of an interface 150, a transceiver 160 (all depicted in dashed lines) and/or other components. In various embodiments, electrical power for mobile electronic device 100 is provided by a mobile power source such as a battery (not shown), when not being actively charged.

Host processor 110 can be one or more microprocessors, central processing units (CPUs), DSPs, general purpose microprocessors, ASICs, ASIPs, FPGAs or other processors which run software programs or applications, which may be stored in host memory 130, associated with the functions and capabilities of mobile electronic device 100.

Host bus 120 may be any suitable bus or interface to include, without limitation, a peripheral component interconnect express (PCIe) bus, a universal serial bus (USB), a universal asynchronous receiver/transmitter (UART) serial bus, a suitable advanced microcontroller bus architecture (AMBA) interface, an Inter-Integrated Circuit (I2C) bus, a serial digital input output (SDIO) bus, a serial peripheral interface (SPI) or other equivalent. In the embodiment shown, host processor 110, host memory 130, display 140, interface 150, transceiver 160, sensor processing unit 170, and other components of mobile electronic device 100 may be coupled communicatively through host bus 120 in order to exchange commands and data. Depending on the architecture, different bus configurations may be employed as desired. For example, additional buses may be used to couple the various components of mobile electronic device 100, such as by using a dedicated bus between host processor 110 and host memory 130.

Host memory 130 can be any suitable type of memory, including but not limited to electronic memory (e.g., read only memory (ROM), random access memory, or other electronic memory), hard disk, optical disk, or some combination thereof. Multiple layers of software can be stored in host memory 130 for use with/operation upon host processor 110. For example, an operating system layer can be provided for mobile electronic device 100 to control and manage system resources in real time, enable functions of application software and other layers, and interface application programs with other software and functions of mobile electronic device 100. Similarly, a user experience system layer may operate upon or be facilitated by the operating system. The user experience system may comprise one or more software application programs such as menu navigation software, games, device function control, gesture recognition, image processing or adjusting, voice recognition, navigation software, communications software (such as telephony or wireless local area network (WLAN) software), and/or any of a wide variety of other software and functional interfaces for interaction with the user can be provided. In some embodiments, multiple different applications can be provided on a single mobile electronic device 100, and in some of those embodiments, multiple applications can run simultaneously as part of the user experience system. In some embodiments, the user experience system, operating system, and/or the host processor 110 may operate in a low-power mode (e.g., a sleep mode) where very few instructions are processed. Such a low-power mode may utilize only a small fraction of the processing power of a full-power mode (e.g., an awake mode) of the host processor 110.

Display 140 may be a liquid crystal device, (organic) light emitting diode device, or other display device suitable for creating and visibly depicting graphic images and/or alphanumeric characters recognizable to a user. Display 140 may be configured to output images viewable by the user and may additionally or alternatively function as a viewfinder for camera.

Interface 150, when included, can be any of a variety of different devices providing input and/or output to a user, such as audio speakers, touch screen, real or virtual buttons, joystick, slider, knob, printer, scanner, computer network I/O device, other connected peripherals and the like.

Transceiver 160, when included, may be one or more of a wired or wireless transceiver which facilitates receipt of data at mobile electronic device 100 from an external transmission source and transmission of data from mobile electronic device 100 to an external recipient. By way of example, and not of limitation, in various embodiments, transceiver 160 comprises one or more of: a cellular transceiver, a wireless local area network transceiver (e.g., a transceiver compliant with one or more Institute of Electrical and Electronics Engineers (IEEE) 802.11 specifications for wireless local area network communication), a wireless personal area network transceiver (e.g., a transceiver compliant with one or more IEEE 802.15 specifications for wireless personal area network communication), and a wired a serial transceiver (e.g., a universal serial bus for wired communication).

Mobile electronic device 100 also includes a general purpose sensor assembly in the form of integrated SPU 170 which includes sensor processor 172, memory 176, a sensor 178, and a bus 174 for facilitating communication between these and other components of SPU 170. In some embodiments, SPU 170 may include at least one additional sensor 180 (shown as sensor 180-1, 180-2, . . . , 180-n) communicatively coupled to bus 174. In an embodiment, one of the sensors, for example, sensor 180-1, may be a MEMS sensor, such as a gyroscope. In some embodiments, all of the components illustrated in SPU 170 may be embodied on a single integrated circuit. It should be appreciated that SPU 170 may be manufactured as a stand-alone unit (e.g., an integrated circuit), that may exist separately from a larger electronic device.

Sensor processor 172 can be one or more microprocessors, CPUs, DSPs, general purpose microprocessors, ASICs. ASIPs, FPGAs or other processors which run software programs, which may be stored in memory 176, associated with the functions of SPU 170.

Bus 174 may be any suitable bus or interface to include, without limitation, a peripheral component interconnect express (PCIe) bus, a universal serial bus (USB), a universal asynchronous receiver/transmitter (DART) serial bus, a suitable advanced microcontroller bus architecture (AMBA) interface, an Inter-Integrated Circuit (I2C) bus, a serial digital input output (SDIO) bus, a serial peripheral interface (SPI) or other equivalent. Depending on the architecture, different bus configurations may be employed as desired. In the embodiment shown, sensor processor 172, memory 176, sensor 178, and other components of SPU 170 may be communicatively coupled through bus 174 in order to exchange data.

Memory 176 can be any suitable type of memory, including but not limited to electronic memory (e.g., read only memory (ROM), random access memory, or other electronic memory). Memory 176 may store algorithms or routines or other instructions for processing data received from sensor 178, which may be an ultrasonic sensor, for example, and/or one or more sensors 180, as well as the received data either in its raw form or after some processing. Such algorithms and routines may be implemented by sensor processor 172 and/or by logic or processing capabilities included in sensor 178 and/or sensor 180.

A sensor 180 may comprise, without imitation; a temperature sensor, a humidity sensor, an atmospheric pressure sensor, an infrared sensor, a radio frequency sensor, a navigation satellite system sensor (such as a global positioning system receiver), an acoustic sensor (e.g., a microphone), an inertial or motion sensor (e.g., a gyroscope, accelerometer, or magnetometer) for measuring the orientation or motion of the sensor in space, or other type of sensor for measuring other physical or environmental quantities. In one example, sensor 180-1 may comprise a gyroscope, sensor 180-2 may comprise an acoustic sensor, and sensor 180-n may comprise a motion sensor.

In some embodiments, sensor 178 and/or one or more sensors 180 may be implemented using a micro-electro-mechanical system (MEMS) that is integrated with sensor processor 172 and one or more other components of SPU 170 in a single chip or package. Although depicted as being included within SPU 170, one, some, or all of sensor 178 and/or one or more sensors 180 may be disposed externally to SPU 170 in various embodiments.

### Example Stress Isolation Frame

Many sensors, such as MEMS sensors, are sensitive to external forces that adversely affect the sensing and lead to inaccurate results. Package stresses are one of the primary sources of offset shift in MEMS gyroscopes. For example, in gyroscopes that include a stress isolation frame and a mechanical element suspended in the frame, tension/compression and bend can cause the stress isolation frame and the mechanical element to deform. Package stresses can also adversely affect the sensing capabilities of other MEMS sensors and other sensors in general. The drive for thinner and more compact mobile devices necessitates components with thinner/smaller packages, resulting in an increased sensitivity to package stresses. This trend is likely to continue in the upcoming years, creating a demand for methods and devices for reducing sensitivity of the MEMS sensors and other sensors to package stresses. Such package stresses also exist for other MEMS sensors, such as accelerometers, Lorentz force magnetometers, membrane sensors, and other MEMS transducers, as well as for non-MEMS sensors, such as magnetometers, clocks, and pressure sensors.

Embodiments described herein provide for the reduction of package sensitivity of MEMS sensors (e.g., gyroscopes, accelerometers, oscillators, etc.), as well as non-MEMS sensors. Embodiments described herein provide improved mechanical isolation of the MEMS sensor or sensor from the package, allowing for improved rejection of the effect of package/PCB stresses on the MEMS sensor's/non-MEMS sensor's mechanical element.

Embodiments of the present invention include a rigid stress isolation frame to keep the mechanical element of the MEMS sensor or other sensor from deforming, and a compliant suspension, such as a crab-leg suspension or folded spring suspension, between an anchor and the stress isolation frame, or rigid frame structure, to prevent package strain from propagating onto the MEMS sensor.

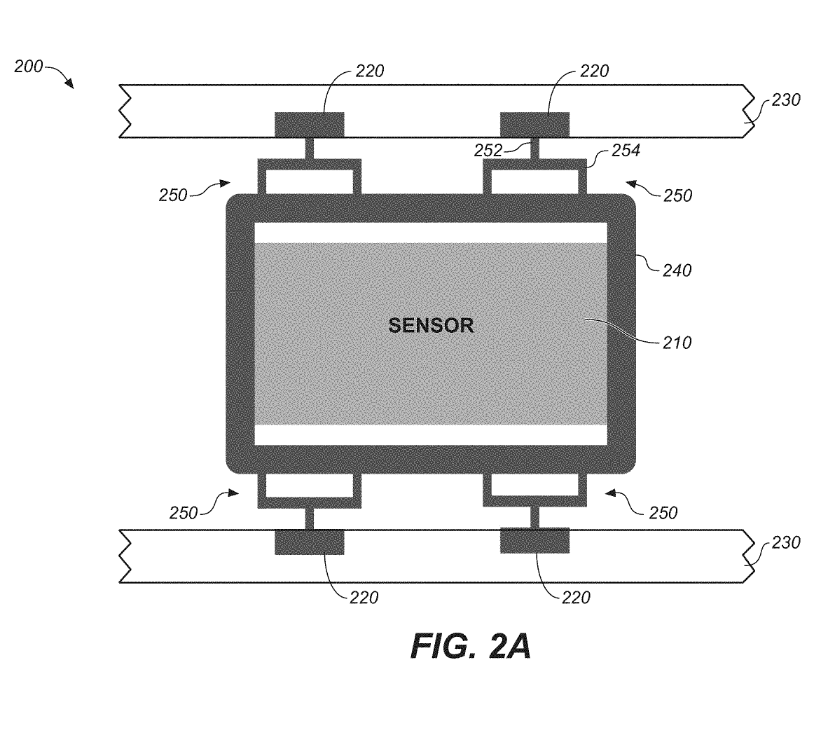

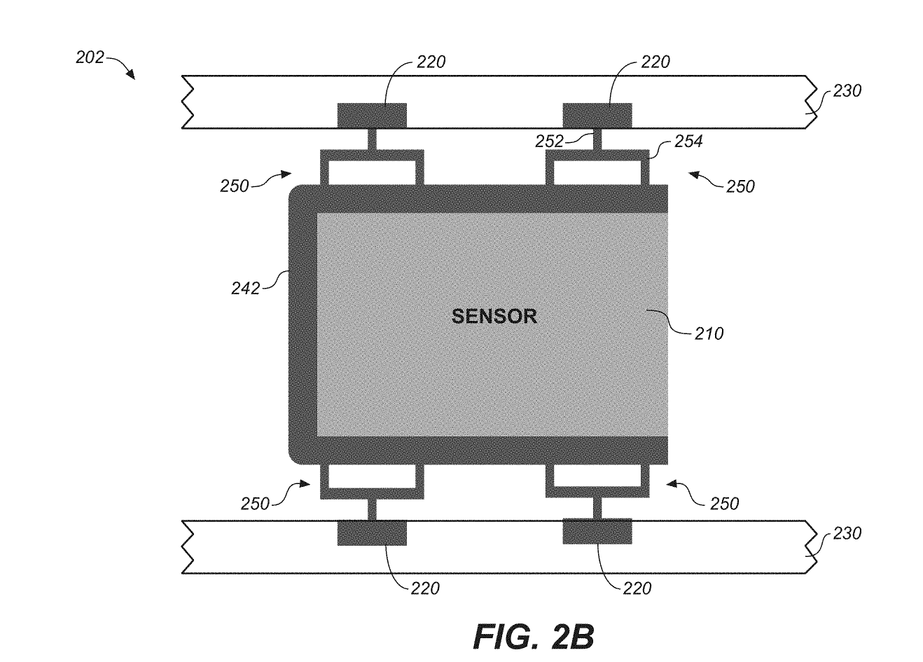

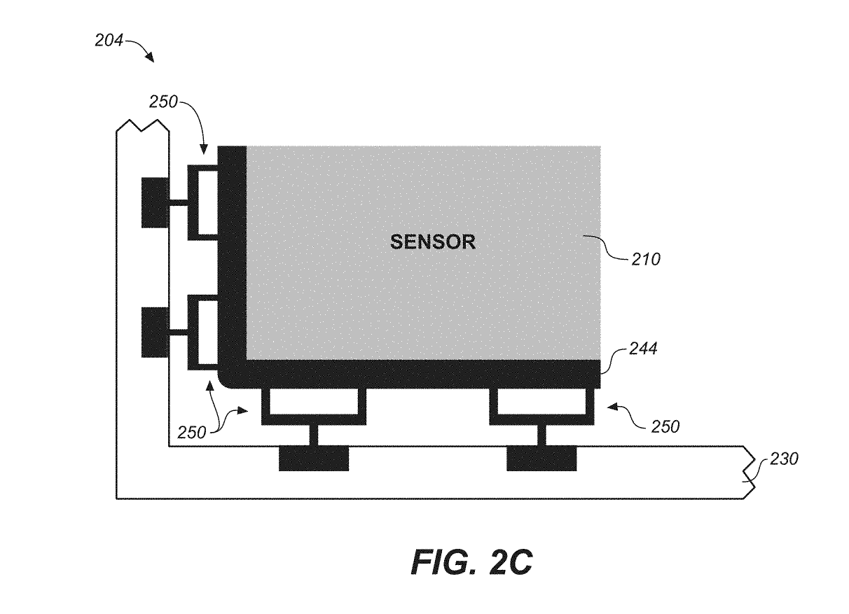

FIG. 2A illustrates a schematic top plan view of a device 200 for reducing package stress sensitivity of a sensor 210. The device 200 comprises one or more anchor points 220 for attaching to a portion of a substrate 230. The device 200 further comprises a rigid frame structure 240 configured to at least partially support the sensor 210. Finally, the device 200 includes a compliant element 250 between each anchor point 220 and the rigid frame structure 240. In the device 200 depicted in FIG. 2A, four anchor points 220 are depicted and four compliant elements 250, each disposed between an anchor point and the rigid frame structure 240, are depicted. However, it should be appreciated that there can be any number of compliant elements 250 not less than one, of which the illustrated embodiment is one example.

The sensor 210 may be one of a micro-electro-mechanical system (MEMS) sensor or a non-MEMS sensor, such as a magnetometer, a dock, or a pressure sensor. The MEMS sensor may be one of a gyroscope, an accelerometer, and a membrane sensor. Other examples of MEMS and non-MEMS sensors are listed in the Background section above.

The sensor 210 may be partially or fully suspended from the rigid frame structure 240. In the device 200 depicted in FIG. 2A, the sensor 210 is shown fully suspended from the rigid frame structure 240.

Each anchor point 220 may be a rectilinear-shaped member embedded in the substrate 230. Each compliant element 250 may comprise one connection 252 (or in some embodiments, two connections 252) to the anchor point 220 and a plurality of connections 254 to the rigid frame structure 240. At least one “leg” 252 of the compliant element 250 may be fixedly attached to the anchor point 220 and at least one “leg” 254 may be fixedly attached to the rigid frame structure 240 to provide a rigid-compliant-rigid connection from anchor point 220 to compliant element 250 to rigid frame structure 240.

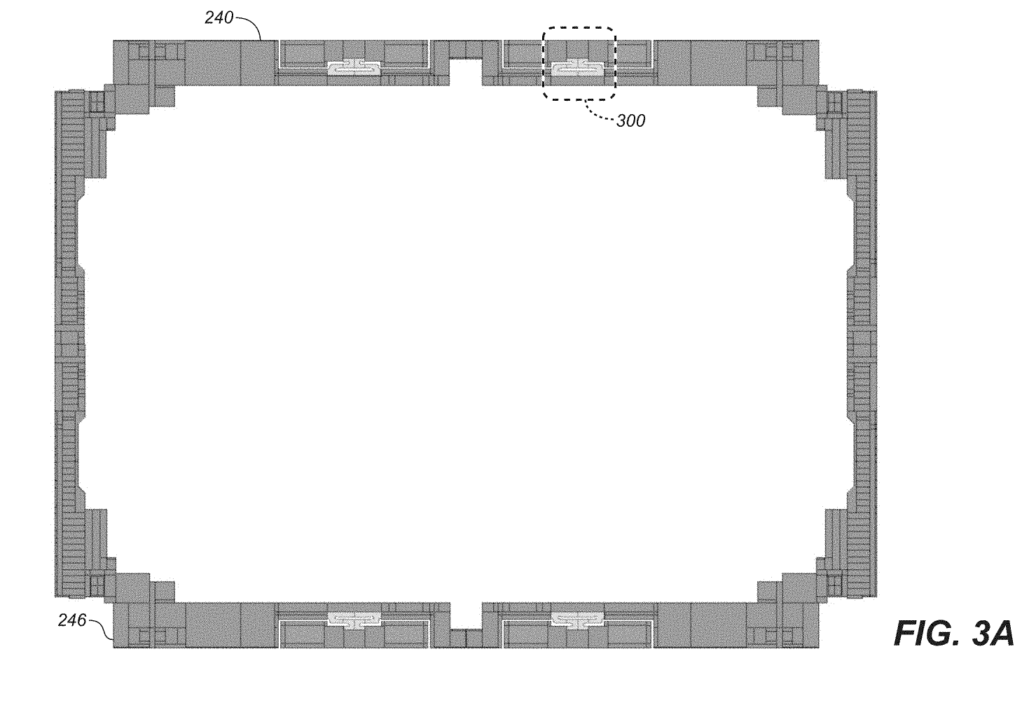

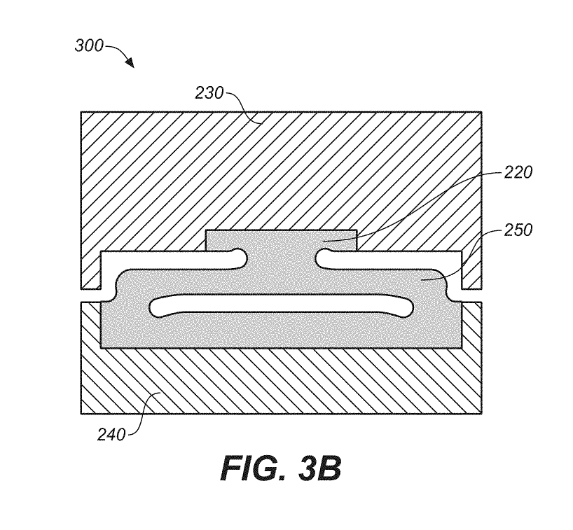

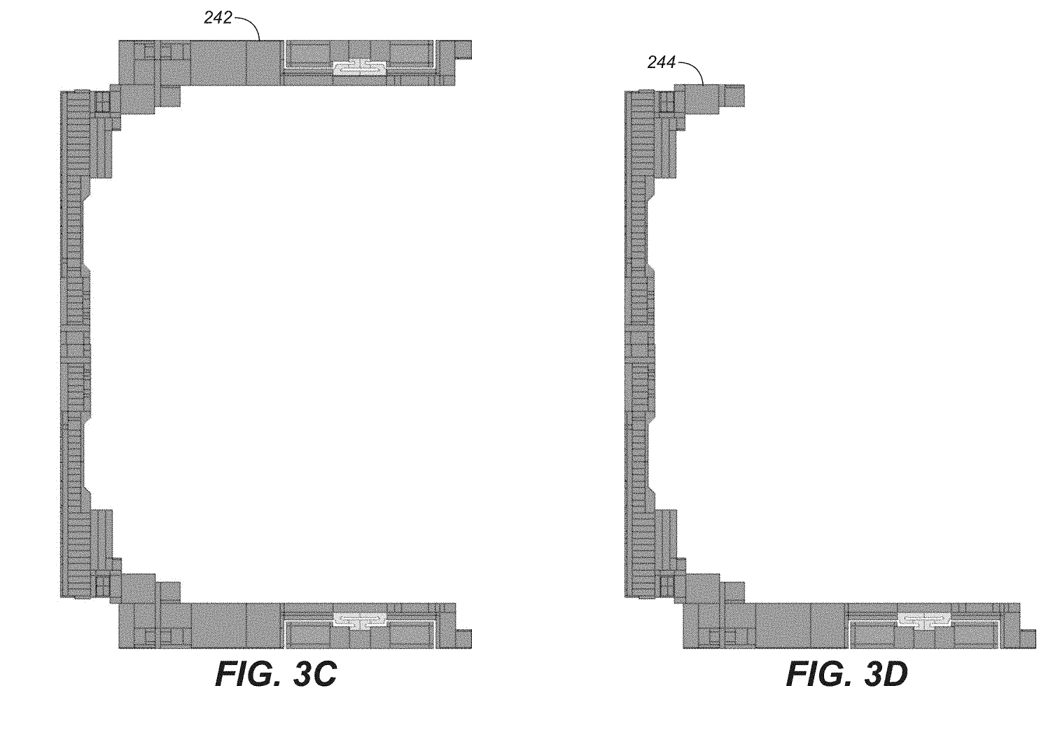

The rigid frame structure 240 may be of any shape that supports and protects the sensor 210. Rigid frame structure 240 fully surrounds sensor 210 on all sides. However, it should be appreciated that the rigid frame structure may have a different shape for supporting sensor 210, e.g., as illustrated in FIGS. 3C and 3D.

The device 200 comprises four anchor points 220 for attaching to a substrate 230. The device 200 further comprises a rigid frame structure 240 configured to support the sensor 210. Finally, the device 200 includes four cab-leg suspension elements 250, one between each anchor point 220 and the rigid frame structure 240. The crab-leg suspension element is compliant.

FIG. 2B illustrates a schematic top plan view of a device 202 for reducing package stress sensitivity of a sensor 210. The device 202 comprises one or more anchor points 220 for attaching to a portion of a substrate 230, a rigid frame structure 242 configured to at least partially support the sensor 210, and a compliant element 250 between each anchor point 220 and the rigid frame structure 242. Rigid frame structure 242 surrounds sensor 210 on three sides.

In the device 202 depicted in FIG. 2B, four anchor points 220 are depicted and four compliant elements 250, each disposed between an anchor point and the rigid frame structure 242, are depicted. However, it should be appreciated that there can be any number of compliant elements 250 not less than two, of which the illustrated embodiment is one example.

FIG. 2C illustrates a schematic top plan view of a device 204 for reducing package stress sensitivity of a sensor 210. The device 204 comprises one or more anchor points 220 for attaching to a portion of a substrate 230, a rigid frame structure 244 configured to at least partially support the sensor 210, and a compliant element 250 between each anchor point 220 and the rigid frame structure 244. Rigid frame structure 244 is L-shaped and surrounds sensor 210 on two sides.

In the device 204 depicted in FIG. 2C, four anchor points 220 are depicted and four compliant elements 250, each disposed between an anchor point and the rigid frame structure 244, are depicted. However, it should be appreciated that there can be any number of compliant elements 250 not less than two, of which the illustrated embodiment is one example.

FIGS. 3A-D illustrate examples of different shapes of the rigid frame structure 240 and includes an enlarged portion 300 that depicts an anchor point 220, attached to a portion of the substrate 230, and a compliant element 250, attached to the rigid frame structure 240. In some embodiments, the rigid frame structure 240, 242, 244 may be a full frame (FIGS. 3A and 33, 240), in other embodiments, a half frame (FIG. 3C, 242), and in still other embodiments, an L-shaped frame (FIG. 3D, 244). In some embodiments, the rigid frame structure 240 may be T-shaped. In other embodiments, a straight edge on at least one side of the sensor element may be used to form the rigid frame structure 240, such as the bottom edge 246 of the frame in FIG. 3A. Also, the rigid frame structure 240 can comprised a few straight edges on each side of the sensor 210 that can be connected together through some connections. In other words, a few straight edges may be used that each cause some isolations but are not necessary form a frame for an L-shape, for example. The rigid frame structure 240, 242, 244 may comprise a material selected from the group consisting of silicon, silicon nitride, silicon oxide (glass), metals and alloys such as aluminum, titanium, steel, copper, gold, and plastics.

The compliant element 250 is more compliant than the rigid frame structure 240. Examples of the compliant element material may be selected from the same group of materials listed for the rigid frame structure 240 above. In some embodiments, both the rigid frame structure 240 and the compliant element 250 may be of the same material, such as silicon. The difference in compliance may be achieved, for example, by a change in the physical dimensions, such as by making the compliant element 250 thinner than the rigid frame structure 240. In some embodiments, the sensor 210, the rigid frame structure 240, and the compliant element 250 may be fabricated in the same process step out of the same layer/material.

The compliant element 250 is a suspension element and may be one of a crab-leg structure, straight beam, and a folded spring. The crab-leg suspension element 250 is depicted in FIGS. 2A-C and 3A.

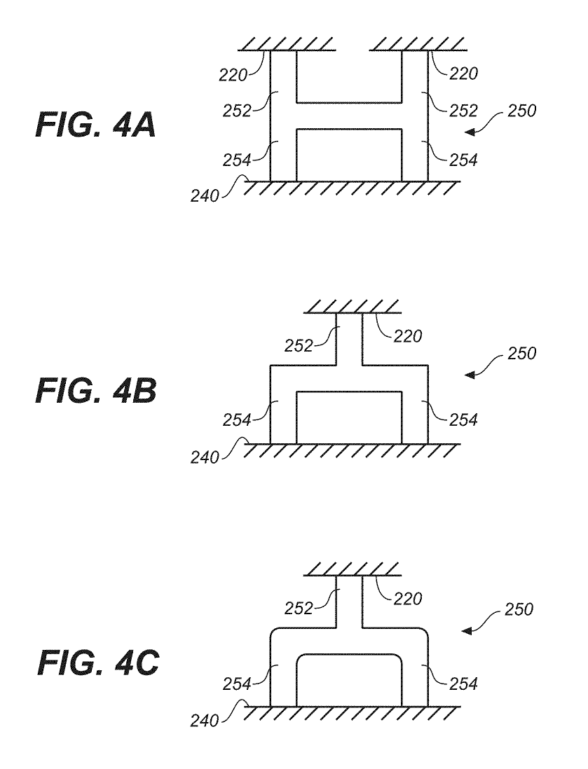

Examples of crab-leg compliant structures 250 are shown in FIGS. 4A-C, but the claims of the present disclosure are not limited to the particular structures shown in FIGS. 4A-C. Rather, the structures 250 are merely exemplary of the various crab-leg structures that may be employed in the practice of the embodiments disclosed herein. An “H” crab-leg structure 250 is shown in FIG. 4A, while inverted “Y” crab-leg structures 250 are shown in FIGS. 4B-C. The structure 250 shown in FIG. 4B is the same as depicted in FIGS. 2A-C and 3A, but the present claims are not to be construed as limited to this particular structure.

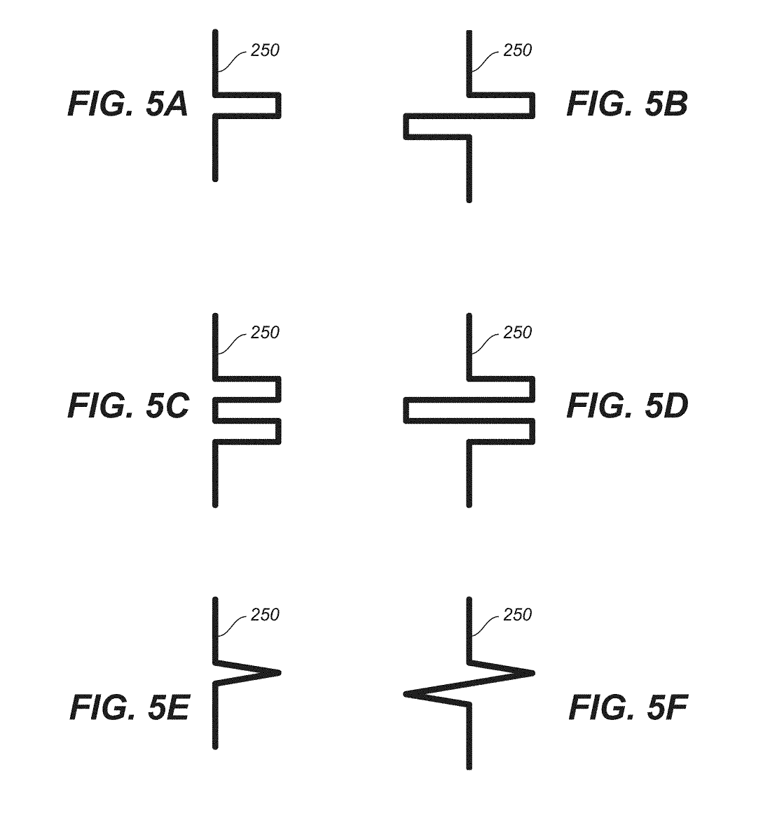

Examples of folded spring compliant structures 250 are shown in FIGS. 5A-F, but the claims of the present disclosure are not limited to the particular structures shown in FIGS. 5A-F. Rather, the structures are merely exemplary of the various folded springs that may be employed in the practice of the embodiments disclosed herein.

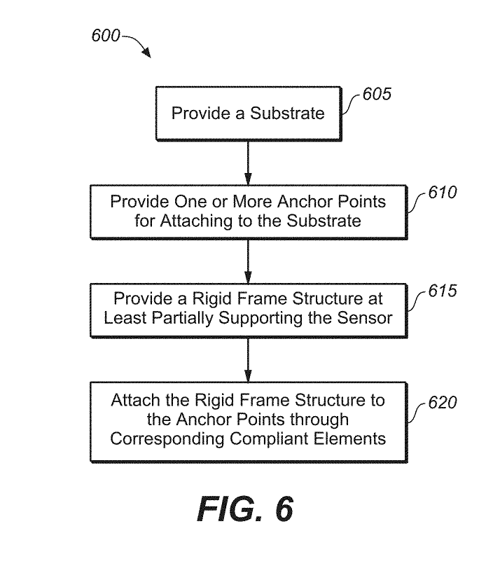

FIG. 6 depicts a method 600 for reducing package stress sensitivity of a sensor 210. The method 600 comprises providing 605 a substrate 230. The method 600 further comprises providing 610 one or more anchor points 220 for attaching to the substrate 230. The method 600 additionally comprises providing 615 a rigid frame structure 240 at least partially supporting the sensor 210. The method still further comprises attaching 620 the rigid frame structure 240 to the anchor points 220 through corresponding compliant elements 250.

Examples of the material for the compliant element 250 may be selected from the same group of materials listed for the rigid frame structure 240 above. Attachment of the rigid frame structure 240 to the sensor 210 or the compliant element 250 to the substrate 230 may be achieved by any of fusion bonding, eutectic bonding, plasma bonding, welding, and adhesive bonding, for example. In addition, the rigid frame structure 240, the compliant element 250, and the sensor 210 may be monolithically fabricated out of same material/layer. Such a monolithic process requires no attachment or bonding.

Fabrication of the rigid frame structure 240 and the compliant element 250 may be achieved by any of etching, patterning, embossing, and machining as a way to fabricate the frame and compliant elements, for example.

In summary, it should be appreciated that the MEMS sensor or non-MEMS sensor can be fully or partially attached onto a stress isolation structure. In various embodiments, the sensor can be a gyroscope, accelerometer, Lorentz force magnetometer or some other MEMS transducer or non-MEMS sensor. It should be appreciated that there can be one or more anchor points to the stress isolation structure. It should be appreciated that the compliant (e.g., suspension) element can be a crab-leg suspension or some other compliant structure.

Embodiments of the present invention use a rigid stress isolation frame and a compliant suspension built into the stress isolation frame, as opposed to attempting to build the compliance into the stress isolation frame itself (rigid stress isolation frame+compliant suspension vs compliant isolation frame+rigid suspension).

It is appreciated that, in the foregoing description, numerous specific details are set forth to provide a thorough understanding of the examples. However, it is appreciated that the examples may be practiced without limitation to these specific details. In other instances, well-known methods and structures may not be described in detail to avoid unnecessarily obscuring the description of the examples. Also; the examples may be used in combination with each other.

While a limited number of examples have been disclosed, it should be understood that there are numerous modifications and variations therefrom. Similar or equal elements in the Figures may be indicated using the same numeral.

What is claimed is:

1. A device for reducing package stress sensitivity of a sensor comprising:
at least one anchor point for attaching to a substrate;
a rigid frame structure configured to at least partially support the sensor; and
a compliant element between each anchor point and the rigid frame structure.

2. The device of claim 1, wherein the sensor is one of a magnetometer, clock, accelerometer, gyroscope, microphone, and pressure sensor.

3. The device of claim 1, wherein the sensor is partially or fully suspended from the rigid frame structure.

4. The device of claim 1, wherein each compliant element comprises at least one connection to an anchor point and a plurality of connections to the rigid frame structure.

5. The device of claim 1, wherein the rigid frame structure is attached to the substrate with four anchor points and four corresponding compliant elements.

6. The device of claim 1, wherein the rigid frame structure is one of a full frame, a half frame, an L-shaped frame, straight edge on at least one side, and a T-shaped frame.

7. The device of claim 6, wherein the rigid frame structure and the compliant element each comprise a material selected from the group consisting of silicon, silicon nitride, silicon oxide, aluminum, titanium, steel, copper, gold, and plastics.

8. The device of claim 7, wherein the material comprising the rigid frame structure is the same or different as the material that comprises the compliant element.

9. The device of claim 8, wherein the compliant element is more compliant than the rigid frame structure.

10. The device of claim 1, wherein the compliant element is a suspension element that is one of a crab-leg structure, straight beam or a folded spring.

11. A device for supporting a micro-electro-mechanical (MEMS) sensor, the device comprising:
four anchor points for attaching to a substrate;
a rigid frame structure configured to support the MEMS sensor; and
a crab-leg suspension element between each anchor point and the rigid frame structure, wherein the crab-leg suspension element is compliant.

12. The device of claim 11, wherein the MEMS sensor is one of a magnetometer, clock, accelerometer, gyroscope, microphone, and pressure sensor.

13. The device of claim 11, wherein each crab-leg suspension element comprises one connection to an anchor point and a plurality of connections to the rigid frame structure.

14. The device of claim 11, wherein the rigid frame structure is one of a full frame, a half frame, an L-shaped frame, straight edge on at least one side, and a T-shaped frame.

15. The device of claim 14, wherein the rigid frame structure and the crab-leg suspension element each comprise a material selected from the group consisting of silicon, silicon nitride, silicon oxide, aluminum, titanium, steel, copper, gold, and plastics.

16. The device of claim 15, wherein the material comprising the rigid frame structure is the same as the material comprising the crab-leg suspension element.

17. The device of claim 16, wherein the crab-leg suspension element is more compliant than the rigid frame structure.

18. A method for reducing package stress sensitivity of a sensor comprising:
providing a substrate;
providing one or more anchor points for attaching to the substrate;
providing a rigid frame structure at least partially supporting the sensor; and
attaching the rigid frame structure to the anchor points through corresponding compliant elements.

19. The method of claim 18, wherein the sensor is one of a magnetometer, clock, accelerometer, gyroscope, microphone, and pressure sensor.

20. The method of claim 18, wherein the compliant element is more compliant than the rigid frame structure.

21. The method of claim 18, wherein the anchor points are attached to the substrate or the compliant elements to the anchor points or the rigid frame structure to the compliant elements by any of fusion bonding, eutectic bonding, plasma bonding, welding, and adhesive bonding.

22. The method of claim 18, wherein the rigid frame structure and the compliant element are fabricated by any of etching, patterning, embossing, and machining.

23. The method of claim 18, wherein the rigid frame structure, the compliant element, and the sensor are monolithically fabricated in the same process step using the same material.
